(19) United States
(12) Patent Application Publication
(10) Pub. No.: US 2025/0261343 A1
(43) Pub. Date: Aug. 14, 2025

(54) LOW-PROFILE, HIGH-GREEN STRENGTH, FLAME-RESISTANT FLEXIBLE HOSE FOR DATACENTER COOLING

(71) Applicant: ContiTech Deutschland GmbH, Hannover (DE)

(72) Inventors: Jason Vallone, Mount Pleasant, IA (US); Carol Sue Hedberg, Norfolk, NE (US); Andrew J. Speidel, Norfolk, NE (US); Phil Wilson, New London, IA (US)

(73) Assignee: ContiTech Deutschland GmbH, Hannover (DE)

(21) Appl. No.: 19/024,177

(22) Filed: Jan. 16, 2025

Related U.S. Application Data
(60) Provisional application No. 63/552,743, filed on Feb. 13, 2024.

(51) Int. Cl. H05K 7/20; C08L 23/16; G06F 1/20

(52) U.S. Cl. CPC H05K 7/20781; C08L 23/16; G06F 1/20

(57) ABSTRACT

A hose and/or a datacenter liquid cooling system with such hose that is flexible and may have high-green strength, flame-resistance, reduced leaching of extractables, and/or a low profile. The inner tube is formed from an elastomeric composition comprising one or more EPDM(s) constituting a majority of base polymer, a filler package, and a peroxide cure package, such that the cured elastomeric composition reduces extractable leaching. The outer cover layer is thin-walled and formed from an elastomeric composition comprising EPDM(s), a filler package, and a cure package, in which the cured elastomeric composition satisfies flammability requirements of UL 94 standard. A dual-denier reinforcement layer includes inner reinforcement yarns between 2,000 to 4,5000 denier, an intermediate layer, and outer reinforcement yarns between 1,000 to 1,500 denier, in which the greater denier inner reinforcement offers burst strength, and the lesser denier outer reinforcement reduces strike through of the thin-walled outer cover layer.

### RELATED APPLICATIONS

This application claims the benefit of U.S. Provisional Application No. 63/552,743 filed Feb. 13, 2024, which is incorporated herein by reference in its entirety.

### TECHNICAL FIELD

The present disclosure relates generally to hose, and more particularly to a flexible hose having high-green strength, reduced permeation, reduced leaching of extractables, flame-resistance, a low-profile, and/or a hybrid reinforcement architecture, such as for use in a datacenter liquid cooling system.

### BACKGROUND

Flexible hoses are used in a variety of applications for transporting fluids such as liquids and gases. For example, one application of a flexible hose is in a direct-to-chip datacenter liquid cooling system that directly cools electronics by circulating a coolant, such as a glycol-propylene mixture, to a cold plate or heat exchanger thermally coupled to the electronic component. The hoses in such a system serve as conduits for transporting the glycol-propylene coolant between components in the cooling system. These hoses are engineered to withstand the chemical properties of the coolant and maintain their structural integrity under operating conditions. They facilitate the efficient flow of coolant from the coolant distribution unit (CDU) to the cooling loops and back to the heat exchangers, ensuring consistent and reliable cooling performance throughout the data center.

### SUMMARY

Over time, computers used in datacenters have required increasingly higher power usage which has led to higher heat loads that must be dissipated. As such, the use of direct-to-chip liquid cooling is becoming increasingly popular. Traditional sulfur cure hoses are currently used for these applications; however, it has been found that such hoses may have issues with permeation of the coolant and/or leaching of extractables into the coolant. Such hoses also should meet the needs of fire resistance for use in such direct liquid cooling systems.

Accordingly, at least one aspect of the present disclosure solves one or more of the foregoing problems by providing a hose that minimizes permeation and/or leaching, and which satisfies testing requirements of the UL 94 standard for flammability.

According to an aspect, a hose suitable for use in a datacenter liquid cooling system includes: an inner tube, a reinforcement layer disposed outwardly of the inner tube, and an outer cover layer disposed outwardly of the reinforcement layer, wherein at least the inner tube is formed from an elastomeric composition comprising one or more EPDMs (ethylene propylene diene monomer elastomer) constituting a majority of the base polymer, a filler package, and a peroxide cure package, such that the elastomeric composition reduces extractable leaching as compared against a same composition using a sulfur cure package instead, and in which, after curing, the hose meets testing requirements of the UL 94 standard.

In exemplary embodiments, the hose meeting the testing requirements of the UL 94 standard may have the same elastomeric composition for the cover layer and inner tube, or the elastomeric compositions between the inner tube and cover layer may be different. For example, the elastomeric composition forming the outer cover layer may be formed from an elastomeric composition comprising EPDM, a filler package, and a sulfur cure package, in which the hose, after curing, meets the testing requirements of UL 94 standard.

Another issue with datacenter liquid cooling systems is that the ever-increasing demand for computing power results in higher density server racks which have less clearance for equipment. These tight space constraints between the server blades have created a need for lower profile hoses that continue to meet the same performance criteria of the hoses that they will replace.

Accordingly, at least one aspect of the present disclosure solves at least the problem associated with tight space constraints by providing a hose having a low profile design.

For example, the exemplary low-profile hose may have a reduced wall thickness of about 20% or more compared to a conventional datacenter cooling hose.

According to certain embodiments, the exemplary low-profile multilayer hose may have an ID in a range from about 3/16-inch to about ⅜-inch and a wall thickness in a range from about 4 mm to about 6 mm; or an ID in a range from about ½-inch to about ¾-inch and a wall thickness in a range from about 6 mm to about 9 mm; or an ID in a range from about 1-inch to about 1.5 inch and a wall thickness in a range from about 9 mm to about 10.5 mm; etc.

According to another aspect, a low-profile multilayer hose has a reduce weight as compared against a conventional hose, for example a reduction in weight in a range from 15% to 30% while still maintaining target ID and working pressure specifications, such as a burst pressure rating up to 200 psi.

At least one problem associated with low-profile (thin-walled) hose is that the elastomeric composition may not have sufficient green strength to be self-supporting during extrusion, which may cause the tube to tear off at the extruder during production. While such low green strength typically is overcome by increasing the thickness (gauge) of the tube wall to make the hose more robust, this may not be a possible solution when there is a desire to maintain a low-profile hose.

Accordingly, at least one aspect of the present disclosure, is to improve the green strength of the elastomeric composition forming at least the inner tube to enable extrusion and result in an overall low-profile hose.

For example, according to an aspect, a multilayer hose includes an inner tube, an outer cover layer, and a reinforcement layer between the inner tube and outer cover layer, wherein at least the inner tube is formed from an elastomeric composition having a green strength that exceeds that of conventional inner tubes, for example exceeding the green tensile strength of a conventional tube by 10 times or more, such as between 10 to 15 times; and/or a green tear die C strength that exceeds that of a conventional tube by four times or more, such as bout five times that of a conventional tube.

In exemplary embodiments, such an elastomeric composition forming the inner tube may have a green strength in terms of one or more of: (i) green tensile strength of greater than 10 psi, more particularly greater than 30 psi, or even more particularly greater than 100 psi, such as in a range from 10 psi to 200 psi, as tested according to ASTM D412; and/or (ii) a green tear die C strength of greater than 40 psi, more particularly greater than 100 psi, or even more particularly greater than 150 or 200 psi, such as in a range from 50 to 250 psi, as tested according to ASTM D624.

According to an aspect, a low-profile hose having suitable green strength for extrusion includes an inner tube, a reinforcement layer disposed outwardly of the inner tube, and an outer cover layer disposed outwardly of the reinforcement layer, wherein at least the inner tube is formed from an elastomeric composition comprising: one or more EPDM(s) having an ethylene content of greater than 65% by weight in which the EPDM(s) constitute a majority of base polymer of the elastomeric composition, a filler package present in a range from 100 phr to 200 phr in which the filler package includes one or more carbon black(s) in a range from 80 phr to 120 phr, and a peroxide cure package present in a range from 5 phr to 10 phr, in which, after curing, the hose meets flammability testing requirements of the UL 94 standard.

Such features of the increased green strength of the elastomeric composition forming at least the inner tube can also improve the resistance of tube collapse during spiral winding of the reinforcement layer during manufacturing.

Another issue with forming low-profile hose is that the reduction of thickness of the cover layer can allow tearing to occur more easily during production.

According to an aspect, a method of manufacture is utilized in which the cover layer is extruded using a knife-edge profile die instead of a conventional flat-landed die profile.

Another issue with forming low-profile hose is that the reduction of thickness of the cover layer can cause the appearance of the underlying reinforcement strands to strike through, causing the thin outer cover layer to look bumpy as there may not be enough elastomeric material to hide the reinforcement strands underneath.

According to an aspect, a low-profile hose includes an inner tube, an outer cover layer, and a reinforcement layer between the inner tube and outer cover layer; wherein the outer cover layer has a low-profile thickness in a range from about 0.8 mm to about 1.2 mm, more particularly about 0.9 mm to about 1.10 mm; and the reinforcement layer includes reinforcement strands adjacent to and in contact with the outer cover layer, wherein a yarn forming the reinforcement strands has a denier in a range from about 1000 denier to about 1500 denier; more particularly wherein the reinforcement strands are arranged in a spiral-wound configuration with greater than 20 ends per yarn.

In certain embodiments, the present disclosure provides a single layer of reinforcement strands in which more total ends (e.g., 20-30) of a smaller denier yarn (e.g., 1000-1500 denier) is used, more particularly wherein the reinforcement strands are formed from aramid or similar high tensile yarn, more particularly wherein the single layer of reinforcement is spirally wound, and even more particularly wherein the single layer of reinforcement strands is utilized for smaller ID hose (e.g., less than ⅝-inch)

According to another aspect, the present disclosure provides a dual- or hybrid-reinforcement arrangement in which the hose includes an inner tube, a reinforcement layer, and a cover layer, wherein the reinforcement layer includes an inner reinforcement layer formed from yarns having a denier in a range between 2,000 to 4,5000 denier; and a second outer reinforcement layer formed from yarns having a denier in a range between 1,000 to 1,500 denier; wherein the inner and outer reinforcement layers are separated by an intermediate elastomeric layer, in which the inner reinforcement layer with the greater denier offers burst strength and the outer reinforcement layer with the lesser denier reduces strike through of the thin-walled outer cover layer; more particularly wherein the first and second reinforcement layers are spiral wound; more particularly wherein the hybrid-reinforcement arrangement is utilized for larger ID hose (e.g., ⅝-inch or greater).

Another issue that can occur by forming low-profile hose is that the conventional steam vulcanization processes may use an air support inside the inner tube so that the hose can keep its shape. However, such support air can cause the hose to inflate, thus increasing the OD of the hose during cure. The air also could react with the peroxide cure package used in the elastomeric composition forming the inner tube of the hose.

According to an aspect, a manufacturing method of forming a hose includes using a low-pressure (e.g., about 120 psi) nitrogen gas support within the inner tube of the hose during vulcanization, thereby reducing oxygen from the inner tube and restricting the formation of defects, while also balancing pressure inside the hose to prevent OD creep.

It is understood that one or more of the foregoing aspect(s) and/or exemplary described feature(s) may be combined separately or together in any suitable manner.

The following description and the annexed drawings set forth certain illustrative embodiments according to the present disclosure. These embodiments are indicative, however, of but a few of the various ways in which the principles of the invention may be employed. Other objects, advantages and novel features according to aspects of the present disclosure will become apparent from the following detailed description when considered in conjunction with the drawings.

### BRIEF DESCRIPTION OF THE DRAWINGS

The annexed drawings, which are not necessarily to scale, show various embodiments according to the present disclosure.

FIG. 1 illustrates an exemplary direct-to-chip liquid cooling system for a datacenter.

FIG. 2 illustrates a perspective cutaway view of a portion of an exemplary hose according to the present disclosure.

FIG. 3 illustrates a perspective cutaway view of a portion of another exemplary hose according to the present disclosure.

FIG. 4 illustrates a cross-sectional view of the hose in FIG. 3.

FIG. 5 is a graph illustrating overall wall thickness vs. outer diameter for a conventional datacenter cooling system hose vs. an exemplary datacenter cooling system hose according to the present disclosure.

### DETAILED DESCRIPTION

The principles and aspects of the present disclosure have particular application to hoses, in particular hoses suitable for use in direct liquid cooling in datacenters, and thus will be described herein chiefly in this context. It is understood, however, that the principles and aspects of the present disclosure may be applicable to other types of hoses for other applications, or to other articles in general, when desirable to provide one or more advantages of the material(s) and/or construction(s) described herein.

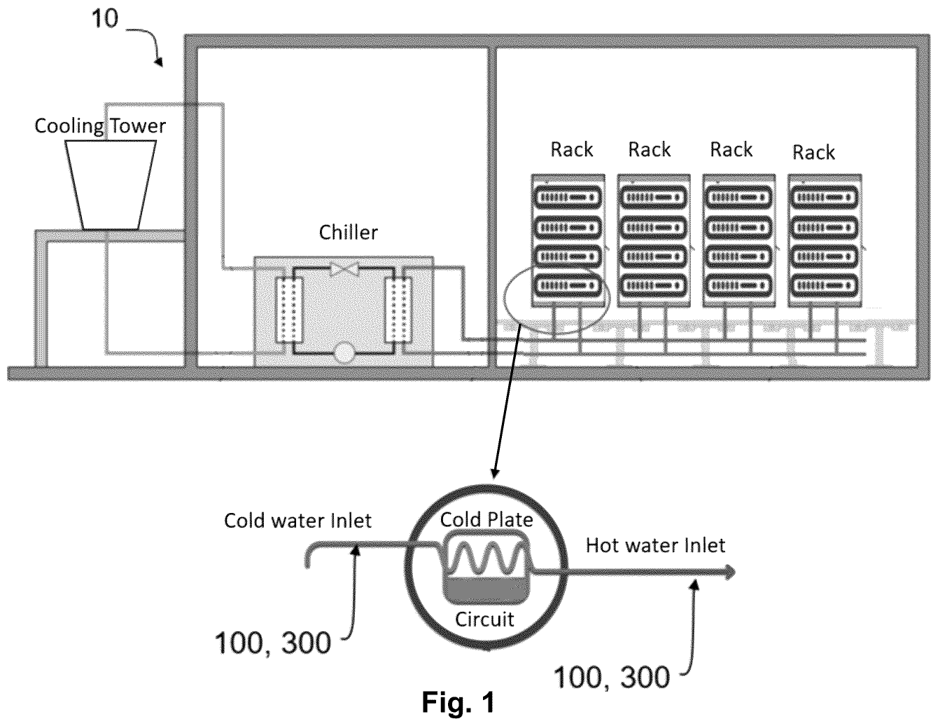

Referring to FIG. 1, an exemplary datacenter liquid cooling system 10 is shown including electronics to be cooled (e.g., CPU/GPUs located in server racks) in which hoses 100, 300 convey cold coolant from a chiller or other heat exchanger to the electronics, such as via cold plates thermally coupled to the electronics. The hoses 100, 300 also convey the coolant heated by extracting heat from the electronics back to the chiller or other heat exchanger. In exemplary embodiments, the coolant may be a glycol-propylene mixture, and the hoses conveying this coolant are engineered to withstand the chemical properties of the coolant and maintain their structural integrity under operating conditions.

### Hose Embodiments

Certain hose embodiments of the disclosure will hereafter be described with reference to the accompanying drawings, in which like reference numerals denote like elements. It should be understood, however, that the accompanying figures illustrate the various implementations described herein and are not meant to limit the scope of various technologies described herein. In addition, it is understood that various aspects and features of these embodiments may be substituted for one another or used in conjunction with one another where applicable. Furthermore, it is understood that the description of material(s) forming the various parts of one embodiment article may be the same material(s) for the same or similar part in another embodiment article, except as otherwise noted below.

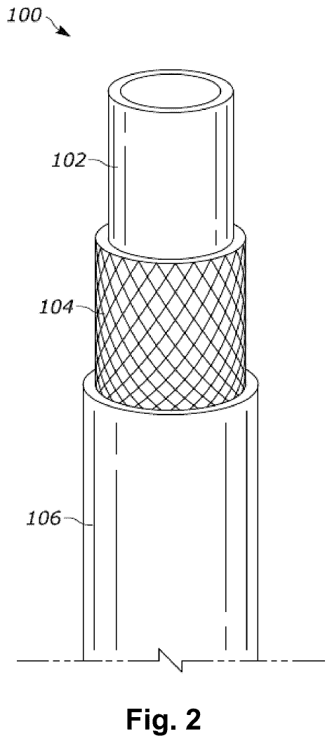

FIG. 2 illustrates an exemplary embodiment of a hose 100 that is suitable for use in a datacenter liquid cooling system, such as that shown in FIG. 1. The hose 100 includes an inner tube 102 that forms an internal fluid passage, or lumen, through which fluid is conveyed. A reinforcing layer 108 is disposed outwardly from the inner tube 102. A cover layer 110 is disposed outwardly from the reinforcing layer 108 and is the outermost layer of the illustrated hose 100.

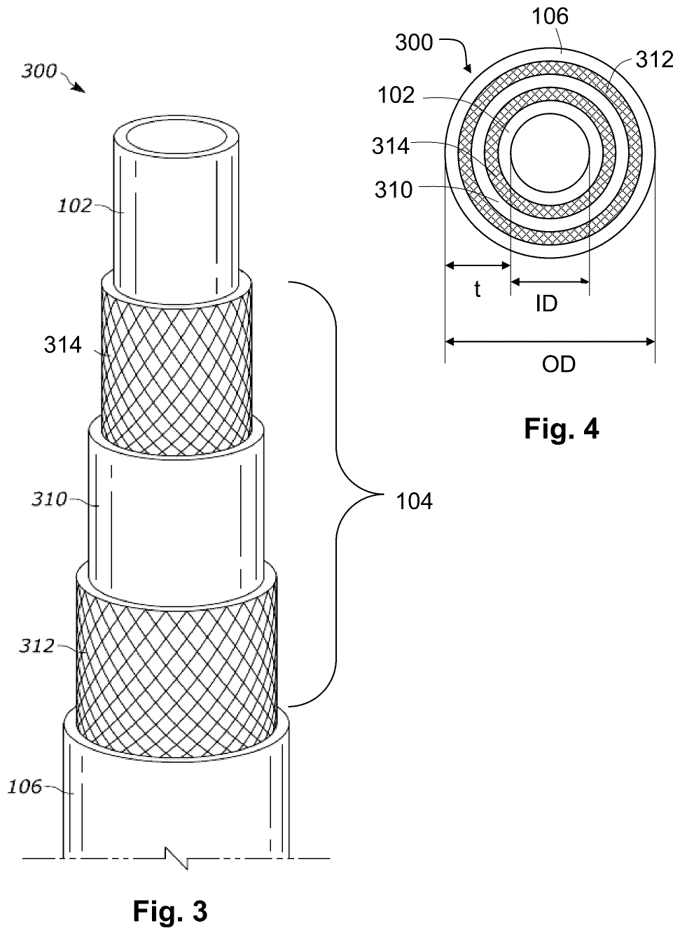

FIG. 3 illustrates another exemplary embodiment of a hose 300 that is suitable for use in a datacenter liquid cooling system. The hose 300 includes inner tube 102, reinforcement layer 104 disposed outwardly of the inner tube 102, and outer cover layer 106 disposed outwardly of reinforcement layer 104. In the embodiment of FIG. 3, the reinforcement layer 104 of hose 300 includes at least two layers of reinforcement 314, 312 which are separated by an intermediate layer 310.

FIG. 4 shows a cross-sectional view of the hose 300 in FIG. 3 illustrating the outer diameter (OD), inner diameter (ID), and the overall wall thickness (t), or gauge thickness, between the OD and ID including the thickness of each respective layer of the hose.

In exemplary embodiments, the overall wall thickness of the hose 100, 300 has a low-profile thickness as compared to conventional hose used for datacenter cooling. This allows improved use and routing of the hose in tight space constraints of higher density datacenters. For example, the hose 100, 300 may a low-profile with an ID in a range from 3/16-inch to ⅜ inch and a wall thickness in a range from about 4 mm to about 6 mm, an ID in a range from ½-inch and a wall thickness in a range from about 6 mm to about 9 mm, an ID in a range from about 1-inch to about 1.5 inch and a wall thickness in a range from about 9 mm to about 10.5 mm, etc. These ranges include values between the stated numbers, and all ranges between such values, and may be approximated within about 0.5 mm of the stated value. Additional examples of suitable wall thicknesses for different sizes of hose are described in further detail below.

The low-profile multilayer hose also may have a reduce weight as compared against a conventional hose, for example a reduction in weight in a range from about 15% to about 30%, while still maintaining the target ID and working pressure specifications, such as a burst pressure rating up to 200 psi for a datacenter liquid cooling system.

The hose 100, 300 also may be sufficiently flexible to enable routing in confined spaces, such as between server blades and racks in a datacenter liquid cooling system. The lower-profile design may facilitate such increase in flexibility over conventional hose.

The different layers of the exemplary hose(s) 100, 300 will be described in further detail below for sake of clarity and not limitation, it being understood that certain embodiments may provide one or more fewer layers or one or more additional layers, as may be desired for the particular application and understood by those having ordinary skill in the art. This could include, for example, (thermoplastic) veneer layer(s), (thermoplastic) barrier layer(s), additional reinforcement layer(s), tie layer(s) or friction layer(s) between layers, or the like.

### Outer Cover Layer

The outer cover layer 106 is located outwardly of the reinforcement layer 104 and serves to protect the inner layers from the environment of the hose when deployed for use in the field. The cover layer 106 may have any suitable configuration and be made of any suitable material. Several factors may be used to determine the construction and/or materials selection for the cover layer 106, including but not limited to abrasion resistance, fire resistance, chemical resistance, economy, formability, aesthetics, or the like.

To maintain the low-profile, light-weight, and/or enhanced flexibility of the hose 100, 300, the outer cover layer 106 may have a relatively thin wall thickness in a range from about 0.80 mm to about 1.20 mm, more particularly from about 0.90 mm to about 1.10 mm.

In addition, the hose 100, 300 being suitable for use as a datacenter liquid cooling hose may be configured to have fire resistance capabilities such that the hose satisfies the testing requirements of the UL 94 standard for flammability (incorporated herein by reference).

The hose meeting the testing requirements of the UL 94 standard may have the same elastomeric composition for the cover layer 106 and inner tube 102, or the elastomeric compositions between the inner tube 102 and cover layer 106 may be different.

For example, the elastomeric composition forming the outer cover layer 106 may be formed from an elastomeric composition comprising EPDM, a filler package, and a sulfur cure package, in which the hose, after curing, meets the testing requirements of UL 94 standard. A suitable composition for the outer cover layer 106 that meets the requirements of the UL 94 standard is described in U.S. Pat. No. 11,215,298 (incorporated herein by reference).

Elastomeric composition(s) which meet the UL 94 standard may be mixtures based upon ethylene propylene diene monomer elastomer (EPDM) in an amount of up to about 30% by weight of the mixtures, and may further include from 0 to 75% by weight calcium carbonate, from 0 to 75% by weight aluminum silicate, from 0 to 50% by weight magnesium oxide, 25% or greater by weight mineral filler(s), and/or 30% or less by weight plasticizer. In some embodiments, the elastomer compositions are devoid of antimony trioxide, zinc borate, aluminum trihydrate and/or halogenated paraffins.

The EPDM elastomer useful in some embodiments of the disclosure is generally a terpolymer of ethylene, propylene, and diene functional monomers. In some aspects, the EPDM elastomer from about 2.5% to about 12% weight of diene functional monomer, and in some other aspects, at least 6% by weight of diene functional monomer. Some nonlimiting examples of EPDM materials useful in some embodiments of the disclosure include those EPDM materials having a weight ratio of ethylene to propylene of from about 1:1 up to about 3:1, ethylidene norbornene diene content of from about 3% to 6% by weight, and a Mooney viscosity of from about 50 to about 75. Some nonlimiting commercially available examples include Royalene® 512, Royalene® 539, Royalene® 563, Vistalon® 5601, Vistalon® 6602, Nordel® 4640, Nordel® 4570, Nordel® 4770, Nordel® 4771, Nordel® 6565, and the like.

Embodiments of the elastomeric composition for the cover layer generally include a filler package to enhance properties, to save money, to facilitate processing, to improve physical properties, or for other reasons. Such fillers include, but are not limited to, calcium carbonate, clay, silica, carbon black, clay, organic fiber, inorganic metal powder, mineral powder, talc, calcium sulfate, calcium silicate, and the like. The filler package may help provide flame resistance, by slowing of preventing the spread of the flame by generation of ash. Typical levels of these individual filler components include from about 10 phr to 350 phr or higher. The compositions may also contain other ingredients in addition to the rubbers, distillates, curatives, and accelerators. These additives are well-known in the art and include activators, processing aids, antioxidant packages, pigments, and the like.

Conventional sulfur curative may be used in some compositions according to the disclosure to provide sulfur cured layers. Sulfur cured describes the vulcanization process typical of making rubber. Such sulfur curatives are well known in the art and include elemental sulfur as well as a variety of organic sulfide, disulfide and polysulfide compounds. Examples include, without limitation, vulcanizing agents such as morpholine disulfide, benzothiazole disulfide, 2-(4′-morpholinodithio) benzothiazole, and thiuram compounds such as tetramethylthiuram disulfide, tetraethylthiuram disulfide and dipentamethylenethiuram tetrasulfide. The vulcanizing agents may be used alone or in combination with each other. In an embodiment, sulfur is used as the curing agent. The sulfur curative may be incorporated in any suitable amount.

In one example, an elastomeric composition for the cover layer 106 that satisfies all testing criteria of the UL 94 standard contains (by weight %) 10% Nordel® 4771 EPDM, 2.5% Nordel® 6565 EPDM, 31.9% calcium carbonate, 38.1% Suprex clay, 3.8% N330 grade carbon black, 3.7% talc, 18% napthenic oil plasticizer, 0.4% zinc oxide, 0.4% benzothiazole disulfide, 0.06% sulfur, 0.1% di(morpholin-4-yl)disulphide, 0.1% Struktol HPS11 processing aid, 0.4% bis(3-triethoxysilylpropyl) tetrasulfide, 0.2% zinc dibutyl dithiocarbamate, 0.3% stearic acid, and 0.1% tetramethylthiuram disulphide.

### Reinforcement Layer

The reinforcement layer 104 provides additional strength to the hose, typically by applying strands of reinforcement. The strands may have any suitable configuration or combination of configurations, and the strands may be made of any suitable material or combination of materials for reinforcing the hose. The reinforcement layer 104 may include one or more layers of such strands, which these strand layers may be directly radially adjacent to each other and/or may be separated by intervening layer(s) of material (e.g., elastomeric layer between strand layers).

The reinforcement material of the strands may include, but is not limited to, metal, synthetic, natural material, or mixtures thereof. For example, the reinforcement strands may be metal wire (such as steel wire, stainless-steel wire, plated-steel wire, plain steel wire, or the like). Synthetic materials may include nylon, vinylon, aramid, rayon, polyester (such as polyethylene terephthalate or polyethylene naphthalate), polyvinyl acetate, polyvinyl alcohol (PVA), poly p-phenylene-2,6-benzobisoxazole (PBO), polypropylene, polyamide, carbon fiber, or the like. Natural, ceramic, mineral, etc. fibers may include cotton, jute, hemp, basalt, glass, or the like. To improve bonding of adjacent elastomeric material to the strands, the strands may be coated with a material, such as resorcinol formaldehyde resin or resorcinol formaldehyde latex (RFL), for example.

The reinforcement strands may include elongated fibers, filaments, threads, wires, or the like, or mixtures thereof, which may be in monofilament or multi-filament form. The individual strands may be grouped together to form bundles, tows, yarns, cords, or the like. Generally, a tow is a bundle of untwisted individual strands, a yarn is a bundle of twisted or cabled individual strands, and a cord is a twisted, braided, or cabled yarn or bundle of yarns. The individual strands or grouping of strands may be arranged in a spiral, braided, knitted, fabric, or wrapped reinforcement construction. In some embodiments, the hose may include one or more of these layers of reinforcement, and each layer may have a different orientation of strand arrangement. For example, where two or more layers of spiral reinforcement may be used, a first layer may be spiral wound in a first winding direction, and a second layer spiral wound in a second winding direction opposite the first winding direction. A braided configuration may include groupings of strands arranged in a 1-over, 1-under braid pattern, a 3-over, 3-under braid pattern, or a 4-over, 4-under braid pattern, or the like.

For the performance characteristics of a datacenter liquid cooling hose, the reinforcement layer 104 may have one or more layers of a spiral-plied arrangement of reinforcement yarns formed from a suitable polymeric material, such as PET, aramid, rayon or the like. When multiple plies of reinforcement strands are utilized, they may be counter wound relative to each other, and may be separated by intermediate layer(s) (e.g., layer 310).

The overall thickness of the reinforcement layer 104 (whether a single ply of reinforcement strands, or multiple plies of reinforcement strands separated by intermediate layer(s)) may be in a range from about 2.5 mm to about 3.0 mm for an ID from 3/16-inch to ⅜-inch; or about 3.5 mm to about 5.0 mm for an ID from ½-inch to ¾-inch; or about 5.5 mm to about 6.5 mm for an ID from 1-inch to 1.5-inch, for example.

Because the cover layer 106 may be relatively thin, as noted above, the appearance of the underlying reinforcement strands could strike through the cover, creating a bumpy appearance. As such, the layer of reinforcement strands adjacent to the cover layer 106 may be formed from a smaller denier yarn, for example 1000-1500 denier.

For smaller ID hose (e.g., less than ⅝-inch), a single layer of reinforcement strands of the smaller denier yarn (e.g., 1000-1500 denier) may be used, which may be configured to have more total ends (e.g., 24-30 ends as compared to 12-20 ends for a conventional hose), and which may be formed from aramid or similar high tensile yarn.

For larger ID hose (e.g., ⅝-inch or greater), the reinforcement layer 104 may include a hybrid reinforcement construction in which the inner reinforcement layer 314 may be formed from larger denier yarns in a range between 2,000 to 4,5000 denier, and the second outer reinforcement layer 312 may be formed from the smaller denier yarns in a range from 1,000 to 1,500 denier. Such an arrangement with larger denier yarns forming the inner reinforcement layer offers suitable burst strength, while the smaller denier yarns forming the outer reinforcement layer reduces strike through of the thin-walled outer cover layer 106.

The intermediate layer 310 between layers of the reinforcement strands 312, 314 may be formed from a suitable elastomeric composition, which generally may be compatible with the elastomeric compositions of the inner tube 102 and/or outer tube 106. The elastomeric composition of the intermediate layer 310 may contain various additives in conventional or suitable amounts known to persons having ordinary skill in the art. Such additives may include, and are not limited to, retardants to prevent an unduly quick cure, antioxidants, adhesion promoters, processing aids, reinforcing agents, talc and fillers, such as carbon black, silica, other mineral fillers, lignin, and the like. Reinforcing fillers are typically utilized at a level which is within the range of about 50 parts per hundred parts of resin (phr) to about 150 phr.

### Inner Tube

The inner tube 102 of the hose 100, 300 is formed from an elastomeric composition which provides flexibility and elasticity, and which is compatible with the fluid being conveyed through the hose.

One problem with certain inner tube compositions, such as those cured with sulfur, is that they may have problems with permeation of the coolant and/or leaching of extractables into the coolant. For example, a datacenter liquid cooling system that uses a glycol-propylene coolant may require limiting sulfur content (e.g., sulfides or sulfates) to below 10 ppm, or less than 1 ppm of the coolant. As such, in exemplary embodiments, the inner tube 102 is formed from an elastomeric composition including EPDM (ethylene propylene diene monomer elastomer), a filler package, and a peroxide cure package, such that the elastomeric composition reduces extractable leaching as compared against a composition using a sulfur cure package instead.

To maintain the low-profile, light-weight, and/or enhanced flexibility of the hose 100, 300, the inner tube 102 may have a relatively thin wall thickness, such as in a range from about 1.0 mm to about 1.5 mm for an ID of 3/16-inch to ⅜-inch; or about 1.5 mm to about 2.0 mm for an ID of ½-inch to ¾-inch; or about 2.0 mm to about 2.5 mm for an ID of about 1-inch to about 1.5-inch.

A problem with such low-profile (thin-walled) hose, however, is that the elastomeric composition may not have sufficient green strength to be self-supporting during extrusion, which may cause the tube to tear off at the extruder during production. While such low green strength typically is overcome by increasing the thickness (gauge) of the tube wall to make the hose more robust, this may not be a possible solution when there is a desire to maintain a low-profile hose.

Accordingly, in exemplary embodiments, the elastomeric composition forming the inner tube 102 has an improved green strength to enable extrusion of a low-profile hose, while also providing low permeation and/or low extractables for the conveying fluid (e.g., glycol-propylene coolant). Such improvements in green strength of the inner tube 102 can also improve the resistance of tube collapse during application of the reinforcement layer during manufacturing.

To provide a low extractable composition with high green strength and other performance requirements suitable for a datacenter cooling hose, the elastomeric composition of the inner tube includes one or more EPDM (ethylene propylene diene monomer) base elastomer(s) having a high ethylene monomer content (e.g., greater than 50%, more particularly greater than 60 or 70%) which is cured with a peroxide cure package.

The one or more base elastomer(s) of the composition form at least part of the matrix and serve as the base of the elastomeric composition. The composition also may contain other polymer(s), such as non-elastomer polymer(s), that are blended with the base elastomer(s) to also form part of the matrix of the composition. The total polymer content forming the base composition (including mixtures of base polymers) is set at 100 phr. The polymer matrix of the elastomeric composition generally will be formed from a majority of elastomer material(s) as opposed to other types of non-elastomer base polymer(s) to provide elastic properties, for example at least 80%, or at least 90% or more elastomer material(s) forming the polymer matrix. The additives in the composition are compounded relative to the total base polymer content of the composition, and as such may be represented in parts per hundred (phr), which means parts by weight per 100 parts by weight of the base polymer(s).

The EPDM base elastomer is a synthetic rubber that is derived from the polymerization of ethylene monomer, propylene monomer, and diene monomer. To enhance the green strength of the elastomeric composition and enable a lower profile hose, the EPDM(s) of the base composition may include a greater proportion of ethylene monomer content, such as greater than 65 wt % ethylene monomer (e.g., 65-75%), with about 25-30 wt. % propylene monomer, and about 3-5 wt. % diene monomer. The Mooney viscosity of such an EPDM elastomer may be between about 70-80 Mooney, for example.

The EPDM elastomer(s) may be present in the elastomeric composition in a total amount of greater than 80 phr, such as 80 phr to 100 phr (including all values between the stated values, and all ranges between such values). In exemplary embodiments, the base polymer in the composition consists essentially of EPDM elastomer(s) (e.g., 99% or more).

In exemplary embodiments, the composition contains a mixture of two different types of EPDMs, including one EPDM with a high ethylene content (e.g., approx. 70 wt. %) and another EPDM with a lower ethylene content (e.g., approx. 65 wt. %). The phr ratio of the high ethylene content EPDM to the lower ethylene content EPDM may be in a range from about 70:30 to about 80:20, more particularly about 75:25.

The elastomeric composition of the inner tube also includes one or more reinforcing agents to enhance specific characteristics, such as the mechanical properties of the elastomeric composition. The reinforcing agent(s) may include, for example, one or more carbon black(s), silica(s), calcium carbonate(s) (chalk), clay(s) (kaolin), aluminum silicate(s), calcium silicate(s), magnesium silicate(s) (talc), or other ceramics or minerals, or mixtures thereof.

In exemplary embodiments, the elastomeric composition contains one or more different types of the reinforcing agent(s). The one or more reinforcing agent(s) may be present in the composition in a total amount from about from about 80 phr to about 150 phr; more particularly from about 90 phr to about 110 phr (including all values between the stated values or ranges and subranges between such values).

In certain embodiments, the elastomeric composition contains one or more types of carbon black(s) as at least one of the additional reinforcing agent(s). Typically, carbon blacks use a naming convention as specified by ASTM D1765 to identify the particular type and size of the carbon black. For N-series carbon blacks, grades range from N110 to N990, in which the first numerical digit designates a size or surface area of the carbon black, and the last two numerical digits designate the structural complexity of the carbon black. A lower first digit (e.g., N100-series) has a smaller particle size, and thus higher surface area, than a higher first digit (e.g., N900-series). Unlike virgin carbon black, recovered carbon black (rCB) does not use the same N-number designation system according to ASTM D1765; however, the rCB still may have at least an equivalent mean particle size as N-series designated virgin carbon black, and thus any designation of an N-type carbon black as used herein encompasses both virgin and other types of equivalent carbon black (e.g., rCB) unless specifically stated otherwise.

In exemplary embodiments, the elastomeric composition contains carbon black(s) in a range between N300-series (e.g., N₂ surface area from about 70 m²/g to about 99 m²/g according to ASTM D3037) and N900-series (e.g., N₂ surface area from about 1 m²/g to about 10 m²/g), in which such carbon blacks(s) are present in the above-noted amounts—e.g., in a total amount from about from about 90 phr to about 100 phr (or subranges thereof). In certain embodiments, the reinforcing agents of the composition consist only of carbon black(s).

In some embodiments, the elastomeric composition may contain a larger size carbon black (e.g., N900-series), and a smaller size carbon black (e.g., N500-series, with an N₂ surface area from about 1 m²/g to about 10 m²/g). A suitable phr ratio of the smaller size carbon black (e.g., N300-series) to the larger size carbon black (e.g., N500-series) may be from about 60:40 to about 80:20; more particularly about 75:25 N500:N900.

The elastomeric composition also may contain one or more plasticizers to increase flexibility, reduce hardness, and/or improve the processing characteristics of the composition. The plasticizer(s) may be of any suitable type or combination of types and may be in any suitable amount(s) as may be desired for the application. For example, the plasticizer(s) may include mineral oils, paraffinic oils, naphthenic oils, aromatic oils, vegetable oils, epoxidized oils, synthetic polymer plasticizers (e.g., liquid polybutene), ester plasticizers (e.g., esters of polycarboxylic acids such as adipic, phosphoric, phthalic, sebacic and higher aliphatic alcohols or phenols), phthalate plasticizers (e.g., Dibutyl phthalate, di-2-ethylhexyl phthalate), sebacate plasticizers (e.g., di-2-ethylhexyl sebacate), phosphate plasticizers (e.g., tricresyl phosphate), ether plasticizers (e.g., dibenzyl ether, polyethers or polyether-thioethers), or the like, or mixtures thereof.

The plasticizer(s) may be present in the elastomeric composition in a total amount from about 20 phr to about 50 phr. In exemplary embodiments, the plasticizer may be a severely hydrotreated naphthenic oil present in a total amount within such a range, such as in a range of about 40 phr to 50 phr.

The elastomeric composition also may include one or more processing aids to improve processing flow, dispersion of fillers, etc. Examples of processing aid(s) may include hydrocarbon (HC) resins, thermoplastic (TP) phenolic resins, fatty acid salts (e.g., zinc stearate, calcium stearate), fatty acid esters, (unsaturated) fatty primary amides, other fatty acid derivatives, or the like, or mixtures thereof.

The one or more processing aid(s) may be present in the elastomeric composition in a total amount from about 1 phr to about 10 phr, more particularly from about 1 phr to about 5 phr.

In exemplary embodiments, the composition contains one or more unsaturated fatty primary amide(s) in a total amount of about 0.5 phr to about 1.5 phr. Such unsaturated fatty primary amides may be derived from oleic acid, for example.

Alternatively or additionally, the composition may contain one or more fatty acid derivatives in a total amount of about 0.5 phr to about 5 phr, such as about 1 phr. Such fatty acid derivatives may be in the form of a blend of two or more esters, amides, or salts of these fatty acids.

The elastomeric composition also may contain one or more antidegradant(s), which may include antioxidants and/or antiozonants, to prevent oxidation and/or the damaging effects of ozone, which can cause cracking and deterioration of the composition. Examples of the antidegradant(s) may include, for example, amines (e.g., naphthylamines, diphenyl amine derivatives, paraphenylenediamines such as N-phenyl-N′-(1,3-dimethylbutyl)-p-phenylenediamine (6PPD), N,N′-diphenyl-p-phenylenediamine (DPPD), N,N′-ditolyl-p-phenylenediamine (DTPD), N-isopropyl-N′-phenyl-p-phenylenediamine (IPPD)), quinolines (e.g., dihydroquinolines such as 2,2,4-trimethyl-1,2-dihydroquinoline (TMQ)), thioesters (e.g., bis-(alkylthiopropionate)diesters, alkylthiodipropionate esters), dithiocarbamates (e.g., nickel or zinc salt thereof), 2-Mercaptobenzimidazole (MBI) (including its metal salt (e.g., Zinc 2-mercaptotolumidazole) (ZMTI)), hydrocarbon wax(es), or the like, or mixtures thereof.

The antidegradant(s) may be present in the elastomeric composition in a total amount from about 1 phr to about 5 phr, more particularly from about 1 phr to about 5 phr (including all values between the stated values or ranges and subranges between such values).

The elastomeric composition also may include one or more activator(s) or co-agents to help activate the curing system and promote the formation of crosslinks between polymer chains during vulcanization. Any suitable activator(s) or combination of activator(s) or co-agent(s) in any suitable quantity may be utilized in the elastomeric composition. This may include, for example, magnesium oxide as an acid receptor, fatty acids or soaps, methacrylates (e.g., trimethylolpropane trimethacrylate-TMPTMA) as co-agents for the peroxide cure package, or the like, or mixtures thereof.

The co-agent(s) or activator(s) may be present in the elastomeric composition in a total amount from about 1 phr to about 15 phr, more particularly from about 1 phr to about 10 phr, more particularly from about 4 phr to about 10 phr (including all values between the stated values or ranges and subranges between such values).

As an example, magnesium oxide may be present in the elastomeric composition in a total amount from about 1 phr to about 5 phr and may serve as an acid receptor.

Alternatively or additionally, methacrylates, such as trimethylolpropane trimethacrylate (TMPTMA) may be used as a co-agent for the peroxide cure package, and may be present in the composition in a total amount from about 1 phr to about 5 phr.

The elastomeric composition also contains one or more vulcanizing agent(s) or curative(s) that cross-link the polymer chains in the base polymer(s), making the composition more elastic and less prone to permanent deformation. The vulcanizing agent(s) include non-sulfur vulcanizing agents, such as peroxides (e.g., organic peroxides such as dicumyl peroxide, bis-(t-butyl peroxy-diisopropyl benzene, t-butyl perbenzoate, di-t-butyl peroxide, 2,5-dimethyl-2,5-di-t-butylperoxyhexane, alpha-alpha-bis(t-butylperoxy) diisopropylbenzene).

The vulcanizing agent(s) may be present in a total amount from about 1 phr to about 10 phr, more particularly from about 5 phr to about 10 phr. In exemplary embodiments, the vulcanizing agent includes a mixture of peroxides, such as dicumyl peroxide vulcup peroxide. An exemplary phr ratio of the peroxides may be about 5:2 dicumyl:vulcup, more particularly about 7:1.5 dicumyl:vulcup.

As noted above, the elastomeric composition for the inner tube may have properties that make it particularly suitable for datacenter liquid cooling applications, and improves one or more characteristics of the elastomeric composition as compared against conventional datacenter cooling hose.

For example, the green strength of the elastomeric composition forming the inner tube 102 may exceed that of conventional inner tubes, for example exceeding the green tensile strength of a conventional tube by 10 times or more, such as between 10 to 15 times; and/or a green tear die C strength that exceeds that of a conventional tube by four times or more, such as bout five times that of a conventional tube.

In exemplary embodiments, the elastomeric composition forming the inner tube may have a green strength in terms of one or more of: (i) green tensile strength of greater than 10 psi, more particularly greater than 30 psi, or even more particularly greater than 100 psi, such as in a range from 10 psi to 200 psi, as tested according to ASTM D412; and/or (ii) a green tear die C strength of greater than 40 psi, more particularly greater than 100 psi, or even more particularly greater than 150 or 200 psi, such as in a range from 50 to 250 psi, as tested according to ASTM D624.

### Examples

Elastomeric compositions were prepared and tested for the purpose of further illustrating the nature of some of the embodiments and aspects of the present disclosure and are not intended as a limitation on the scope thereof. The test data for these evaluations are shown in Tables 1 and 2.

In the test data, the evaluations for tensile strength, elongation %, and modulus were conducted according to ASTM D412, and are shown as original (unaged) properties. Hardness testing was conducted according to ASTM D2240. DIN abrasion resistance testing was performed in accordance with ASTM D 5963. Mooney scorch was conducted on a Mooney rheometer (small rotor). Die C tear testing was conducted in accordance with ASTM D624.

Referring to Table 1, various elastomeric formulations for different test samples are shown. This includes Examples 1-4 that use peroxide curative and an EPDM with less ethylene content, and Examples 5-7 that use peroxide cured EPDM having a greater ethylene content.

TABLE 1

| Ingredient | Ex. 1 | Ex. 2 | Ex. 3 | Ex. 4 | Ex. 5 | Ex. 6 | Ex. 7 |
|---|---|---|---|---|---|---|---|
| EPDM: 56/44/6 | 79 | 79 | 79 | 79 | 50 | 0 | 0 |
| E/P/D | | | | | | | |
| EPDM: 68/32/4 | 21 | 21 | 21 | 21 | 50 | 21 | 0 |
| E/P/D | | | | | | | |
| EPDM: 74/26/5 | 0 | 0 | 0 | 0 | 0 | 79 | 100 |
| E/P/D | | | | | | | |
| Carbon black: | 74 | 100 | 74 | 74 | 74 | 74 | 74 |
| N550 | | | | | | | |
| Carbon black: | 26 | 0 | 26 | 26 | 26 | 26 | 26 |
| N990 | | | | | | | |
| Plasticizer: | 45 | 45 | 45 | 45 | 45 | 45 | 45 |
| hydrotreated | | | | | | | |
| naphthenic | | | | | | | |
| process oil | | | | | | | |
| Process aid: | 1 | 1 | 1 | 1 | 1 | 1 | 1 |
| fatty acid | | | | | | | |
| derivatives | | | | | | | |
| Process aid: | 0.5 | 0.5 | 0.5 | 0.5 | 0.5 | 0.5 | 0.5 |
| Unsaturated | | | | | | | |
| fatty primary | | | | | | | |
| amides | | | | | | | |
| Antidegradent | 1 | 1 | 1 | 1 | 1 | 1 | 1 |
| Acid Receptor: | 4.2 | 4.2 | 4.2 | 4.2 | 4.2 | 4.2 | 4.2 |
| MgO | | | | | | | |
| Vulcanizing | 7.33 | 7.33 | 8 | 7.33 | 7.33 | 7.33 | 7.33 |
| Agent: Dicumyl | | | | | | | |
| peroxide | | | | | | | |
| Vulcanizing | 1.4 | 1.4 | 0 | 1.4 | 1.4 | 1.4 | 1.4 |
| Agent: Vuclup | | | | | | | |
| peroxide | | | | | | | |
| Peroxide | 0 | 0 | 2.78 | 2.78 | 0 | 0 | 0 |
| coagent: | | | | | | | |
| TMPTMA | | | | | | | |
| Total Running | 260.43 | 260.43 | 262.48 | 263.21 | 260.43 | 260.43 | 260.43 |
| PHR | | | | | | | |

Table 2 shows the test data including green strength and original physical testing results of the samples in Table 1.

TABLE 2

| | | | | | | |
|---|---|---|---|---|---|---|
| Ex. 1 | Ex. 2 | Ex. 3 | Ex. 4 | Ex. 5 | Ex. 6 | Ex. 7 |

Mooney Scorch 30 mins/270 F.

| | | | | | | | |
|---|---|---|---|---|---|---|---|
| initial | 36.51 | 47.22 | 40.28 | 38.07 | 37.28 | 35.57 | 37.32 |
| ML | 25.61 | 35.2 | 27.17 | 26.66 | 26.09 | 26.3 | 28.09 |
| t5 | 7.83 | 4.99 | 5.66 | 5.57 | 7.54 | 7.88 | 7.4 |

Green strength (Modulus) - dumbbell

| | | | | | | | | |
|---|---|---|---|---|---|---|---|---|
| Tensile | (N/mm²) | 9.44 | 8.49 | 7.19 | 7.05 | 32.16 | 144.36 | 118.77 |
| Elongation | (%) | 194 | 292 | 258 | 210 | 416 | 178 | 354 |
| hardness | shore A | 49 | 55 | 48 | 49 | 52 | 61 | 66 |
| mod 10 | (N/mm²) | 0.301 | 0.366 | 0.278 | 0.296 | 0.364 | 0.648 | 0.735 |
| mod 25 | (N/mm²) | 0.403 | 0.482 | 0.366 | 0.377 | 0.514 | 1.014 | 1.13 |
| mod 50 | (N/mm²) | 0.45 | 0.517 | 0.4 | 0.408 | 0.629 | 1.437 | 1.621 |
| mod100 | (N/mm²) | 0.51 | 0.507 | 0.412 | 0.412 | 1.293 | 4.898 | 3.161 |
| Green Strength | (Ibf/in) | 40 | 49 | 39 | 38 | 89 | 198 | 218 |
| (Modulus) - tear | | | | | | | | |
| Die C | | | | | | | | |

Original Physicals cured 60 mins/315 F.

| | | | | | | | | |
|---|---|---|---|---|---|---|---|---|
| Tensile | (psi) | 2089 | 2096 | 2092 | 2197 | 2183 | 2447 | 2472 |
| Elongation | (%) | 393 | 318 | 345 | 330 | 396 | 381 | 348 |
| 50% Modulus | (psi) | 195 | 256 | 219 | 237 | 225 | 329 | 356 |
| 100% Modulus | (psi) | 363 | 523 | 446 | 491 | 429 | 617 | 663 |
| Hardness | Shore A | 62 | 68 | 65 | 65 | 66 | 73 | 75 |

As shown in the data, the compounds with lower ethylene content EPDM have low green strength in terms of tensile and tear Die C, which was found to cause issues with the tube tearing off at the extruder while in serial production. The results of the examples in Ex. 6 and Ex. 7, which have a greater proportion of higher ethylene content EPDM were found to significantly improve at least the green tensile strength and green Die C tear strength. Specifically, Ex. 6 and Ex. 7 were found to have increased green tensile strength of 12 to 14 times that of Ex. 1 and an increased green Die C tear strength of 5 times that of Ex. 1.

Table 3 shows hose dimensions for a traditional datacenter cooling hose compared to hose dimensions for an exemplary low-profile datacenter cooling hose according to the present disclosure.

TABLE 3

| | | Traditional | High Flex & | | | | |
|---|---|---|---|---|---|---|---|
| | | Hose OD | Low Profile | | | | |
| | | Dimension | Hose OD | Overall | Tube | Cover | |
| Hose ID | ID | Nominal | Nominal | Gage | Gage | Gage | Reinforcement |
| (inch) | (mm) | (mm) | (mm) | (mm) | (mm) | (mm) | gage (mm) |
| 3/16″ | 4.76 | 11.20 | 10.00 | 5.24 | 1.40 | 0.90 | 2.94 |
| ¼″ | 6.35 | 12.70 | 11.20 | 4.85 | 1.40 | 0.90 | 2.55 |
| ⅜″ | 9.53 | 17.00 | 14.80 | 5.28 | 1.40 | 0.90 | 2.98 |
| ½″ | 12.70 | 20.60 | 18.80 | 6.10 | 1.50 | 1.10 | 3.50 |
| ⅝″ | 15.88 | 24.60 | 23.00 | 7.13 | 1.50 | 0.90 | 4.73 |
| ¾″ | 19.05 | 28.50 | 26.60 | 7.55 | 1.70 | 0.90 | 4.95 |
| 1″ | 25.40 | 36.80 | 34.60 | 9.20 | 2.20 | 0.90 | 6.10 |
| 1 ¼″ | 31.75 | 44.00 | 41.00 | 9.25 | 2.40 | 0.90 | 5.95 |
| 1 ½″ | 38.10 | 50.30 | 47.40 | 9.30 | 2.40 | 0.90 | 6.00 |

The data shows that the exemplary low-profile hose may reduce the overall wall (gage) thickness by about 20% over a range of inner diameters for different size hoses.

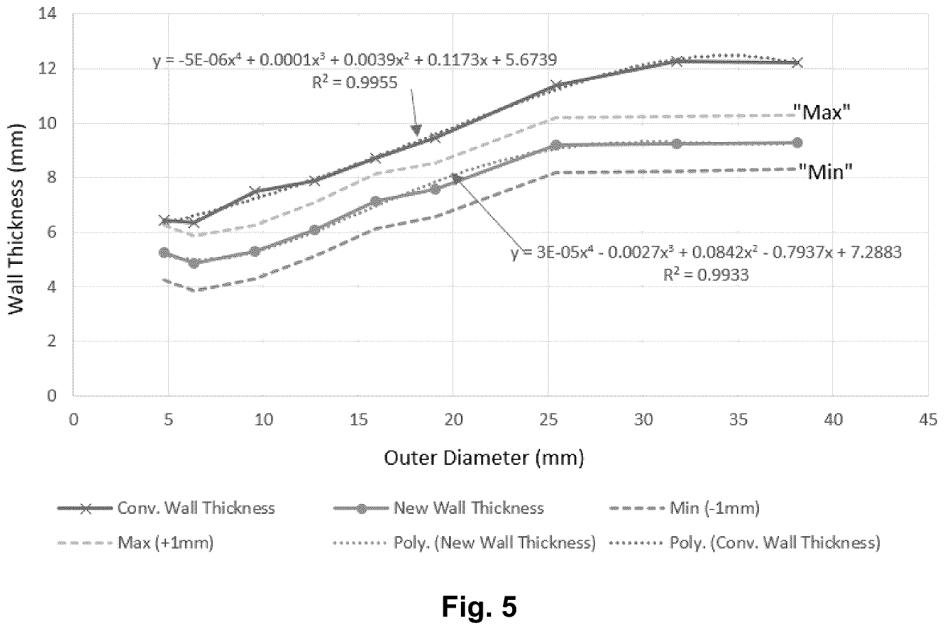

This data is plotted in FIG. 5, and a trend line applied to each of the datasets. A +1 mm maximum and −1 mm minimum of the OD also is shown in the graph to illustrate possible ranges of the low-profile hose.

According to the trendline of such results, an overall wall thickness between the inner diameter at the inner tube and the outer diameter at the outer cover layer may be plus or minus 1 mm of a relationship according to y=3E−05x⁴−0.0027x³+0.0842x²−0.7937x+7.2883, in which y represents the wall thickness (between OD and ID) and x represents the internal diameter (ID).

### Method of Manufacture

An exemplary method of forming the hose 100, 300 may include at least the following steps: applying a first elastomeric composition for forming the inner tube 102; applying reinforcement around the first elastomeric composition for forming at least part of the reinforcement layer 104; applying a second elastomeric composition for forming the cover layer 106 around the reinforcement layer 104; and co-curing at least the first and second elastomeric compositions.

The manufacturing method may include suitable extrusion processes for forming the inner tube and outer cover layer.

A problem with forming low-profile hose, however, is that the reduction of thickness of the layers can allow tearing to occur more easily during extrusion.

According to an aspect, a method of manufacture is utilized in which at least the cover layer, which may be relatively thin compared to the inner tube, is extruded using a knife-edge profile die instead of a conventional flat-landed die profile.

Another issue that can occur by forming low-profile hose is that conventional steam vulcanization processes may use an air support inside the inner tube so that the hose can keep its shape. However, such support air can cause the hose to inflate, thus increasing the OD of the hose during cure. The air also could react with the peroxide cure package used in the elastomeric composition forming the inner tube of the hose.

Accordingly, the manufacturing method of forming a hose may include using a low-pressure nitrogen gas support within the inner tube of the hose during vulcanization, thereby reducing oxygen from the inner tube and restricting the formation of defects, while also balancing pressure inside the hose to prevent OD creep. This low pressure of nitrogen gas may be set at slightly larger than the pressure inside the cure vessel (approximately 120 psi), but preferably not more than a few psi greater than this, so at about 120-125 psi for example, so as to restrict inflation of the inner tube.

The foregoing description of the embodiments has been provided for purposes of illustration and description. Example embodiments are provided so that this disclosure will be sufficiently thorough, and will convey the scope to those who are skilled in the art. Numerous specific details are set forth such as examples of specific components, devices, and methods, to provide a thorough understanding of embodiments of the disclosure, but are not intended to be exhaustive or to limit the disclosure. It will be appreciated that it is within the scope of the disclosure that individual elements or features of a particular embodiment are generally not limited to that particular embodiment, but, where applicable, are interchangeable and can be used in a selected embodiment, even if not specifically shown or described. Thus, while a particular feature may have been described with respect to only one or more of several embodiments, such feature may be combined with one or more other features of the other embodiments, separately or in any combination. The same may also be varied in many ways. Such variations are not to be regarded as a departure from the disclosure, and all such modifications are intended to be included within the scope of the disclosure. as may be desired and advantageous for any given or particular application.

Any background information contained in this disclosure is to facilitate a better understanding of the various aspects described herein. It should be understood that any such background statements are to be read in this light, and not as admissions of prior art. Likewise, the description and examples are presented herein solely for the purpose of illustrating the various embodiments of the disclosure and should not be construed as a limitation to the scope and applicability of the disclosure.

The phrase “and/or” as used in this disclosure should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

The word “or” as used in this disclosure should be understood as being inclusive and not exclusive. For example, when separating items in a list, “or” or “and/or” shall be interpreted as being inclusive, i.e., the inclusion of at least one, but also including more than one, of a number or list of elements, and, optionally, additional unlisted items. For example, a condition A or B is satisfied by anyone of the following: A is true (or present) and B is false (or not present), A is false (or not present) and B is true (or present), and both A and B are true (or present). Only terms clearly indicating exclusivity should be interpreted as indicating exclusive alternatives (i.e. “one or the other but not both”), such as “either,” “only one of,” or “exactly one of.” In other words, such terms of exclusivity refer to the inclusion of exactly one element of a number or list of elements.

Any references to “one embodiment” or “an embodiment” as used herein is understood to mean that a particular element, feature, structure, or characteristic described in connection with the embodiment is included in at least one embodiment. The appearances of the phrase “in one embodiment” in various places in the specification are not necessarily referring to the same embodiment.

In addition, use of the “a” or “an” are employed to describe elements and components of the embodiments herein. This is done merely for convenience and to give a general sense of concepts according to the disclosure. This description should be read to include one or at least one and the singular also includes the plural unless otherwise stated.

The word “exemplary” is used herein to mean “serving as an example or illustration.” Any aspect or design described herein as “exemplary” is not necessarily to be construed as preferred or advantageous over other aspects or designs. Likewise, the phrases “particularly,” “preferably,” or the like as used in this disclosure may refer to an element or value that provides advantage(s) in some embodiment(s), however is not intended to limit the scope of the disclosure to those “particular” or “preferable” features.

Transitional language such as “including,” “comprising,” “having,” “containing,” “involving,” or variations thereof, is intended to be broad and encompass the subject matter listed thereafter, equivalents, and additional subject matter not recited, i.e., to be open-ended and meaning including but not limited to.

It is to be understood that terms such as “top,” “bottom,” “left,” “right,” “front,” “rear,” or the like may refer to an arbitrary frame of reference, rather than to the ordinary gravitational frame of reference. Likewise, spatially relative terms, such as “inner”, “adjacent”, “outer,” “beneath,” “below,” “lower,” “above,” “upper,” or the like, may be used herein for ease of description to describe one element or feature's relationship to another element(s) or feature(s) as illustrated in the figures. Spatially relative terms may be intended to encompass different orientations of the article in use or operation in addition to the orientation depicted in the figures. For example, if the article in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

Terms such as first, second, third, etc. may be used herein to describe various elements, components, regions, layers and/or sections, in which it is understood that these elements, components, regions, layers and/or sections should not be limited by these terms unless stated otherwise. In addition, terms such as “first,” “second,” and other numerical terms when used herein do not imply a sequence or order unless clearly indicated by the context. Thus, a first element, component, region, layer or section discussed herein could be termed a second element, component, region, layer or section without departing from the teachings of this disclosure.

It is to be understood that all values, ranges, ratios or the like as described in this disclosure may be combined in any manner. In addition, it is to be understood that a concentration or amount or value range listed in this disclosure is intended to include any and every concentration or amount or value within the range, including the end points, as if each value within the range has been expressly stated. For example, “a range of from 1 to 10” is to be read as indicating each and every possible number along the continuum between about 1 and about 10. Thus, even if specific data points within the range, or even no data points within the range, are explicitly identified or refer to only a few specific data points, it is to be understood that the inventor(s) appreciate and understand that any and all data points within the range are to be considered to have been specified, and that inventor(s) had possession of the entire range and all points within the range.

In addition, each numerical value used in this disclosure should be read once as modified by the term “about” (unless already expressly so modified), and then read again as not so modified unless otherwise indicated in context. The term “about” as used herein refers to any value which lies within the range defined by a variation of up to ±10% of the stated value, for example, ±10%, ±9%, ±8%, ±7%, ±6%, ±5%, ±4%, ±3%, ±2%, ±1%, ±0.01%, or ±0.0% of the stated value, as well as values intervening such stated values. When the term “about” is used in describing a value or an end-point of a range, the disclosure should be understood to include the specific value or end-point referred to.

The term “consisting essentially of” in relation to a composition is to indicate that substantially (e.g., greater than 95 weight % or greater than 99 weight %) of the component(s) present in the composition is the component(s) recited. Therefore, this term does not exclude the presence of minor additives or impurities as would be understood by those having ordinary skill in the art.

Although the invention has been shown and described with respect to a certain embodiment or embodiments, it is apparent that equivalent alterations and modifications will occur to those having ordinary skill in the art upon the reading and understanding this disclosure, and such modifications are intended to be included within the scope of this disclosure as defined in the claims. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein

What is claimed is:

1. A datacenter cooling system, comprising:
an electronic device mounted to a cold plate;
a liquid heat exchanger; and
a hose directly or indirectly fluidly connecting the liquid heat exchanger to the cold plate, the hose comprising:
an inner tube, a reinforcement layer disposed outwardly of the inner tube, and an outer cover layer disposed outwardly of the reinforcement layer,
wherein the inner tube is formed from an elastomeric composition comprising one or more ethylene propylene diene monomer elastomer(s) (EPDM) constituting a majority of base polymer, a filler package present in a range from 100 phr to 200 phr in which the filler package includes one or more carbon black(s) in a range from 80 phr to 120 phr, and a peroxide cure package present in a range from 5 phr to 10 phr, such that the elastomeric composition, when cured, reduces extractable leaching as compared against a same composition using a sulfur cure package instead;
wherein the outer cover layer is a thin-walled outer cover layer having a thickness in a range from 0.8 mm to 1.2 mm, and the outer cover layer is formed from an elastomeric composition comprising one or more EPDM(s), a filler package, and a cure package, in which the elastomeric composition of the outer cover layer, when cured, satisfies flammability testing requirements of UL 94 standard; and
wherein the reinforcement layer includes an inner reinforcement layer formed from yarns having a denier in a range between 2,000 to 4,5000 denier; and a second outer reinforcement layer formed from yarns having a denier in a range between 1,000 to 1,500 denier; wherein the inner and outer reinforcement layers are separated by an intermediate elastomeric layer; wherein the inner reinforcement layer with greater denier offers burst strength, and the outer reinforcement layer with lesser denier reduces strike through of the thin-walled outer cover layer.

2. The data center according to claim 1, wherein the yarns of the inner reinforcement layer are arranged in a spiral-wound configuration.

3. The data center according to claim 2, wherein the yarns of the inner reinforcement layer are arranged with greater than 20 ends per yarn.

4. The data center according to claim 3, wherein the yarns of the inner reinforcement layer are arranged with up to about 30 ends per yarn.

5. The data center according to claim 2, wherein the yarns of the outer reinforcement layer are arranged in a spiral-wound configuration.

6. The data center according to claim 1, wherein the elastomeric composition forming the inner tube has a green strength in in a range from 10 psi to 200 psi, as tested according to ASTM D412.

7. The data center according to claim 6, wherein the elastomeric composition forming the inner tube has a green tensile strength in a range from greater than 100 psi to 200 psi, as tested according to ASTM D412.

8. The data center according to claim 7, wherein the elastomeric composition forming the inner tube has a green tear die C strength in a range from 50 to 250 psi, as tested according to ASTM D624.

9. The data center according to claim 8, wherein the elastomeric composition forming the inner tube has a green tear die C strength in a range from greater than 100 psi to 250 psi, as tested according to ASTM D624.

10. The data center according to claim 9, wherein the EPDM(s) of the inner tube comprise 65 wt % to 75 wt. % ethylene monomer, 25-30 wt. % propylene monomer, and 3-5 wt. % diene monomer, and have a Mooney viscosity between 70-80 Mooney.

11. The data center according to claim 1, wherein the hose has an overall wall thickness between the inner diameter at the inner tube and the outer diameter at the outer cove layer that is plus or minus 1 mm of a relationship according to y=3E−05x⁴−0.0027x³+0.0842x²−0.7937x+7.2883, in which y represents the wall thickness (between OD and ID) and x represents the internal diameter (ID).

12. The data center according to claim 1, wherein the yarns of the inner reinforcement layer and the yarns of the outer reinforcement layer are formed a polymeric material.

13. The data center according to claim 12, wherein the yarns of the inner reinforcement layer and the yarns of the outer reinforcement layer are selected from PET, aramid, rayon, or mixtures thereof.

14. A method of using the cooling system according to claim 1, comprising:
conveying a coolant through the hose.

15. The method according to claim 14, wherein the coolant is a glycol-propylene mixture.
